(19) United States
(12) Patent Application Publication
(10) Pub. No.: US 2016/0225733 A1
(43) Pub. Date: Aug. 4, 2016

(54) Chip Scale Package

(71) Applicant: DIODES INCORPORATION, Plano, TX (US)

(72) Inventor: Duane Thomas Wilcoxen, Dallas, TX (US)

(21) Appl. No.: 14/915,814

(22) PCT Filed: Nov. 25, 2014
(86) PCT No.: PCT/US2014/067505

§ 371 Date: Mar. 1, 2016

Related U.S. Application Data
(60) Provisional application No. 61/908,895, filed on Nov. 26, 2013.

(51) Int. Cl. H01L 23/00; H01L 21/78; H01L 21/56; H01L 21/3105; H01L 23/31; H01L 23/29

(52) U.S. Cl. CPC H01L 24/14; H01L 23/3135; H01L 23/295; H01L 21/561; H01L 21/565; H01L 21/31053; H01L 24/11; H01L 21/78; H01L 23/3114; H01L 24/94; H01L 2224/13022; H01L 2224/13644; H01L 2224/13155; H01L 2224/1182; H01L 2224/13147; H01L 2224/13669; H01L 2924/10253

(57) ABSTRACT

A novel semiconductor chip scale package encapsulates a semiconductor chip on the device side, the non-device side, and the four edges with a mold compound. One process to fabricate such a semiconductor chip scale package involves forming trenches on the surface of a wafer around the chips and filling the trenches and covering the device side of the chips with a first mold compound. The wafer is subsequently thinned from the non-device side until the bottom portion of the trenches and the mold compound in the portion are also removed. The thinning process creates a plane that contains the back side of the chips and the mold compound exposed in the trench. This plane is subsequently covered with a second mold compound.

### BACKGROUND

Generally speaking, a chip scale package (CSP) is a semiconductor device package with a footprint that is no greater than about 1.2 times the size of the semiconductor chip inside the package. It usually contains a single-chip and is surface mountable.

Some CSPs include leadframe. In such packages, the semiconductor chip is mounted on a leadframe either on the device side—the side on which the semiconductor circuit element or elements are fabricated, or on the non-device side opposite the device side. The chip is bonded to the leadframe with solder or epoxy. Some with bond wires to connect the chip electrically to the leads. The packages are often enclosed with a thermoset or thermoplastic mold compound—a mixture of epoxy resin and filler particles. The mold compound encapsulates the chip and portions of the leadframe. The parts of leadframe that are exposed from the plastic enclosure are there to connect the package electrically to the outside world, usually by soldering. In packages with leadframe, the chips are usually singulated from the wafer and mounted on the leadframe before encapsulation.

Some CSPs do not include a leadframe in this type of package the chips often come with solder bumps or other metallic bumps on the device side and they may be molded in mold compound in wafer form before being singulated. The wafer may be molded on one side or both sides before it is sawed apart to separate the chips. As a result of the sawing, the edges of the chips are exposed from the plastic enclosure.

### SUMMARY

The Inventor recognizes that even though the CSPs of today serve the need of the market place, they have shortcomings.

For instance, CSPs with leadframe cannot be thinner than the combined thickness of the chip and the leadframe. As the chips are routinely being thinned to about 50 pm or less, the leadframe has become the limiting factor to the thickness of the package in some cases. Wire loops of the bond wires add to the package thickness and the leadframe also adds thermal resistance to the package.

The CSP without leadframe, on the other hand, expose at least the edges of the fragile semiconductor chip to the often hostile environment in which the packages reside and function This is so because the wafer is molded before the sawing step and the sawing cuts through the wafer, and exposes the edges of the chip. There are attempts to encapsulate the ex posed edges with extra process steps but none has achieved the cost-performance need of the market.

To remedy the inadequacies of today's CSPs, the Inventor endeavored to invent novel chip scale packages that do not require a leadframe and the package shields the chip on all sides and edges with rugged encapsulation material.

The following paragraphs summarize the novel aspects of the structure of the packages and the processes of fabricating the packages. More detailed description of exemplary embodiments of the invention will be presented in later sections of this paper.

The invented process includes trenching the wafer along the scribe lines around the chips to a depth that passes the device elements and stops before it reaches the back surface of the wafer. After trenching, the chips are still connected to the bottom portion of the wafer and are like mesas surrounded by the trenches on all edges, Mechanical saving, reactive ion, etching, laser heating, wafer jet, other methods known in the art, or their combination may all be used for trenching.

The trenches are then filled in with mold compound—a mixture of epoxy resin and filler particles with a transfer molding process. The mold compound covers the trenches and the device side of the wafer on which projecting contact bumps are formed. If the tips of the contact bumps are covered by mold compound, it may be removed with a light mechanical grinding or a chemical washing, or a combination of chemical and mechanical scrubbing. Alight plating step may be necessary after the removal step to promote the solderability of the contact bumps to the printed circuit board.

The molded wafer is then thinned down from the back side, i.e., the non-device side to separate the chips from one another. The thinning process may involve mechanical grinding, chemical polishing, or a combination of both. Mechanical grinding or polishing may leave grinding line traces on the non-device side of the chips and on the surface of mold compound in the trench, It also leaves partially ground filler particles near the finishing plane embedded in the mold compound.

At this stage of the process flow, the edges and the device side of the chips are well covered by the mold compound. If it is desirous to provide the similar protection to the non-device side of the chips, a second molding step may be performed on the ground surface of the wafer. The second molding may be a transfer molding similar to the first molding step or it may be lamination, and the mold compound of the two molding steps may or may not be same. For instance, they may have different filler particle sizes or concentrations. The two step process maybe evidenced by the presence of a seam plane at the interface of the two layers of mold compound.

The novel package contains a thin chip of which the sides and the edges are all covered with mold compound. The package does not contain a lead frame and the bonding wires associated with leadframe.

The chip has metallic contact bumps that project from the chip. The contact bumps are also covered with the mold compound except at the top where the contact bumps are to make electrical contacts to print circuit board.

### BRIEF DESCRIPTION OF DRAWING FIGURES

FIG. 1 through FIG. 6 depicts the process flow that embodies some aspects of this invention.

FIG. 7 depicts a cross section view of a semiconductor device package that embodies same aspects of this invention.

FIG. 8 depicts a semiconductor device package partially fabricated according to some aspects of this invention.

FIG. 9 is another micrographic depiction of a semiconductor device package partially fabricated according to some aspects of this invention.

FIG. 10 is another micrographic depiction of a semiconductor device package partially fabricated according to some aspects of this invention.

### DETAILED DESCRIPTION

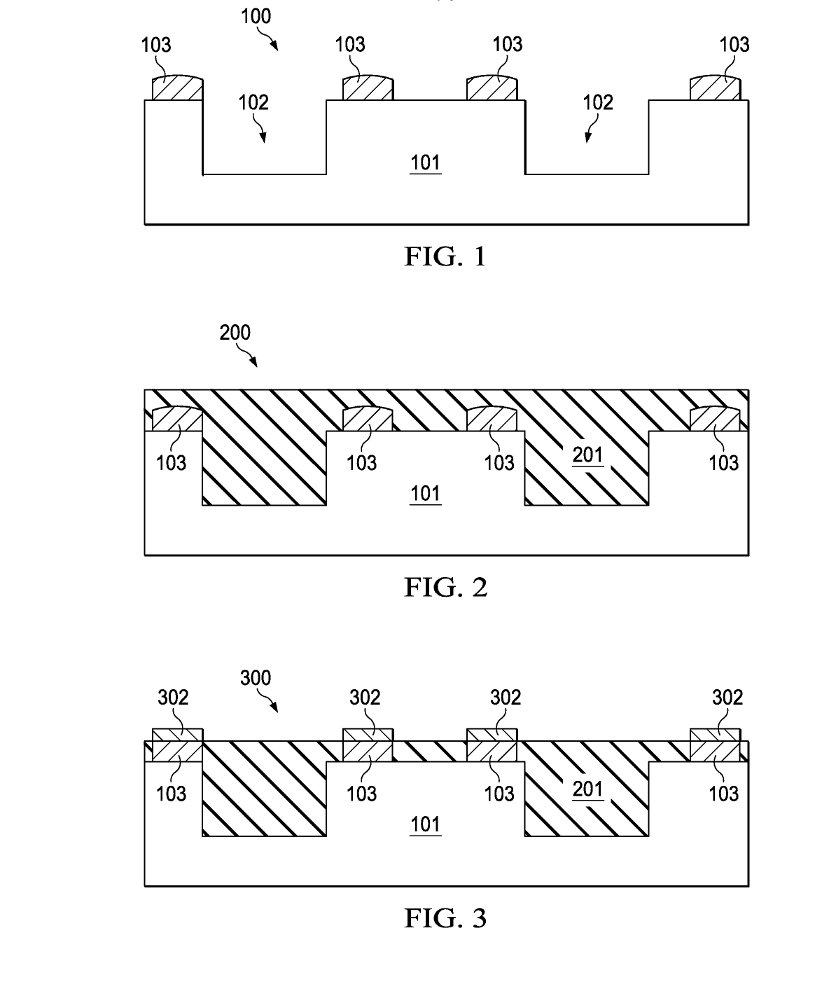

FIG. 1 through FIG. 6 depicts a process flow that embodies some aspects of this invention. The package 100 depicted in FIG. 1 comprises a silicon wafer 101 with integrated circuit elements fabricated in it. Although the wafer used in the illustrative flow is silicon, this process may also be performed on semiconductor other than silicon such as silicon carbide, gallium nitride, etc. The integrated circuit elements are manifested by the nickel bumps 103 through which the integrated circuit may be connected to a printed circuit board.

In this illustrative process the nickel bumps are plated on the silicon wafer surface to a thickness of about 30 μm. In alternative processes, copper may be used instead of nickel. The bumps may be plated to a thickness more, or less than 30 μm.

Also depicted in FIG. 1 are two trenches 102 formed in the silicon wafer 101. The trenches may be cut by the sawing process that is customarily used in the art of semiconductor device assembly except the trenches do not reach the back side of the wafer. In this illustrative process, the depth of the trenches is about 300 μm and is deeper than tile integrated circuit elements in the silicon wafer.

Methods other than sawing, such as reactive ion etching (RCE), laser heating, and water jet may also be used to form the trench as known in the art.

FIG. 2 depicts the wafer in a later stage of the process flow. In FIG. 2, the trenches are shown as filled with mold compound 201 with a transfer molding step known in the art. In this illustrative process flow the mold compound is a mixture of epoxy and filler particles. The trenches in FIG. 2 are about 140 μm wide and some filler particles have diameter about 25 μm.

In this illustrative process flow, the mold compound material 201 as applied may cover the top of the contact bumps 103 and must be removed. There are other molding processes that will leave the top of the contact bumps free of mold compound. One such process involves lining the inner surface of the mold cavity with an elastic film. The film covers the top portion of the contact bumps and keeps the area from the mold compound. The film adds cost to the molding process but saves the cost involved in the cleaning process afterwards.

In this illustrative process flow, a light chemical mechanical polish (CMP) known in the art is used successfully in the removal of mold compound from the top area of the contact bumps 103. Following the CMP step, the contact bumps are plated with a thin layer of metallic material 302 that is wettable in soldering processes known in the art. In this illustrative process flow, the metallic material includes gold.

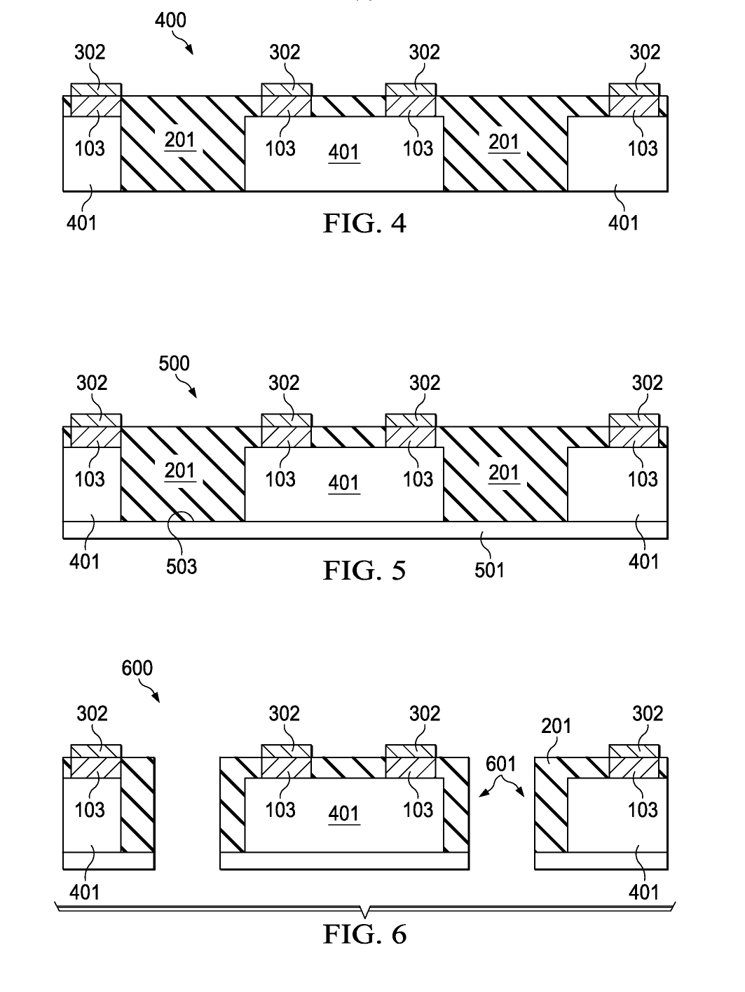

FIG. 4 depicts the semiconductor device package in a later stage of the process flow. Before this stage the individual silicon chips and the back portion of the silicon wafer below the bottom of the trenches are one unitary piece. Even though the silicon chips are clearly delineated by the trenches around them, they are all connected to the back portion of the silicon wafer. As depicted in FIG. 4, the back portion of the silicon wafer that connects the individual chips is removed and the individual silicon chips 401 are severed from their neighbors.

In this illustrative process flow, the back portion of the silicon wafer is removed by a back-grinding process known in the art. Tile grinding passes the bottom of the trenches and separates the individual silicon chips.

The grinding process not only removes the back portion of the silicon wafer but also a portion of the mold compound near the bottom of the trenches. And at the completion of the grinding step, the back side of each silicon chip is coplanar with the surface of the mold compound in the trenches around the silicon chip. The co-planarity is evident in FIG. 10 as between the back surface of the silicon chip 1001 and the bottom of the mold compound and where some filler particles 1002 are partially ground.

At the completion of the grinding operation, individual silicon chips 401 are severed from the neighboring chips but are held together by the mold compound in the trenches and the shape of the wafer maintained. A stress relief step may be taken to remove some damaged silicon from the back side with chemical or plasma etch and that may create a small step in the order of micrometers between the mold compound and the back side of the chips.

FIG. 5 depict the semiconductor device package 500 in a later stage of the process flow. In this illustrative flow, a second layer of mold compound material 501 is applied to the backside of the silicon chips. The second layer of mold compound 501 meets the first layer of mold compound at the surface 503 which is coplanar to the back of the chip 401. The second layer mold compound may be applied with a transfer molding process. Or it may be laminated.

After the second layer of mold compound is cured, the individual devices may be electrically tested, marked, and singulated. FIG. 6 depicts the individual devices 601 following singulation.

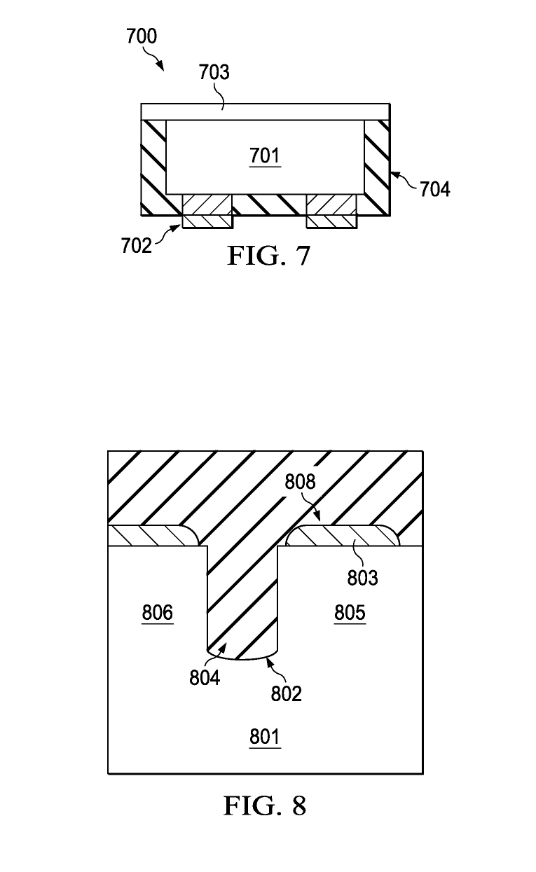

FIG. 7 depicts a typical semiconductor device package that embodies aspects of this invention. Element 701 is the silicon chip with integrated circuit elements connected to the contact bumps 702. The silicon chip 701 and the contact bumps 702 are encapsulated with a first layer of mold compound 704 and a second layer of mold compound 703. The back side of the silicon chip is coplanar with the interface between the first mold compound layer 704 and the first mold compound layer 703.

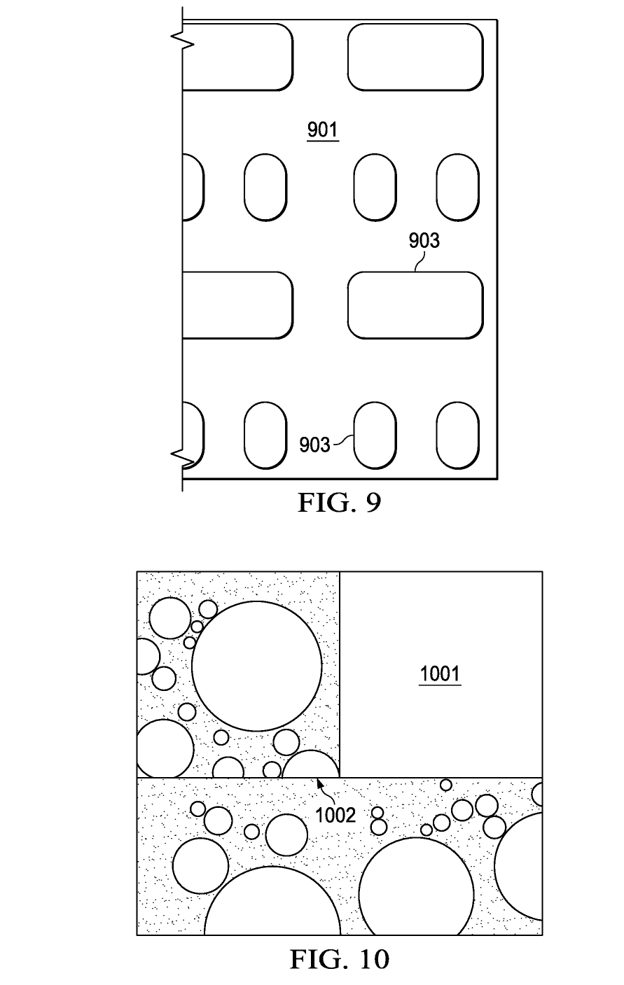

In FIG. 8, element 801 depicts a portion of a silicon wafer. Element 802 depicts a trench formed between silicon chips 806 and 806 in the silicon wafer 801 and as being filled with mold compound 804. Element 803 is a contact bump made of nickel metal. Element 808 is excess mold compound over the top surface of the contact bumps 803. FIG. 9 depicts a portion of the front side of a silicon wafer 901 post a chemical mechanical polish (CMP) process, At this stage of the process flow, the top surfaces of the contact bumps 903 are clear of mold compound. In order to enhance the solderability of the contact bumps to metal pads on printed circuit board, the surface of the contact bumps may be coated with a thin metallic film that contains noble metal such as gold or platinum at this stage.

The process flow and the semiconductor device packages fabricated with the process flow are for demonstrative purposes only and they do flat limit the scope of the invention, which is described in the appending claims.

I claim:

1. A semiconductor device package, comprising:
a semiconductor chip having a device side with metallic contact bumps thereon, a non-device side opposite the device side, and four edges;
a first layer of mold compound covering the four edges and the device side of the chip;
a second layer of mold compound covering the non-device side of the chip; and
the first layer of mold compound joining the second layer of mold compound at a plane that is coplanar to the non-device side of the chip.

2. The semiconductor device package of claim 1, in which a top portion of the contact bumps on the device side of the semiconductor chip protrude from the first layer of mold compound.

3. The semiconductor device package of claim 2, in which the protruding portion of the contact bumps is covered with a metallic film containing gold.

4. The semiconductor device package of claim 3, in which the contact bums nickel.

5. The semiconductor device package of claim 1, in which the first layer of mold compound contains filler particles.

6. The semiconductor device package of claim 5, further comprising partially ground filler particles near the plane where the first layer and the second layer of mold compound meet.

7. The semiconductor of claim 6, in which the partially ground filler particles are embedded in the first layer of mold compound.

8. The semiconductor of claim 7, in which the partially ground filler particles are not embedded in the second mold compound.

9. A process of fabricating a semiconductor device package, comprising:
providing a semiconductor wafer with chips, each chip having a device side, a non-device side and four edges;
covering with a first mold compound the device side and the four edges of the semiconductor chip;
removing a portion of the semiconductor chip from the non-device side and a portion of the first mold compound to create a plane; and
covering the plane with a second mold compound.

10. The process of claim 9, further comprising forming trenches around the chips.

11. The process of claim 10 in which the step of covering with first mold compound comprising filling the trenches with the first mold compound.

12. The process of claim 11, in which the removing step comprises removing the first mold compound from a portion of the trenches.

13. The process of claim 12, in which the removing step comprising a mechanical grinding process.

14. The process of claim 13, in which the grinding process leaves partially ground filler particles near the plane.

15. The process of claim 9, further comprising forming contact bumps on the device side of the chips.

16. The process of claim 15, in which the covering with a first mold compound step comprising uncovering a top portion of the contact bumps from the first mold compound.

17. The process of claim 16, further comprising coating the uncovered portion of the contact bumps with a noble metal, including gold.
